(19) United States
(12) Patent Application Publication
(10) Pub. No.: US 2023/0134115 A1
(43) Pub. Date: May 4, 2023

(54) WAVELENGTH STABILIZER AND OPTICAL MODULE INCLUDING SAME

(71) Applicant: KOREA ELECTRONICS TECHNOLOGY INSTITUTE, Seongnam-si (KR)

(72) Inventor: Byongjin MA, Seongnam-si (KR)

(21) Appl. No.: 18/047,548

(22) Filed: Oct. 18, 2022

(30) Foreign Application Priority Data
Oct. 28, 2021 (KR) 10-2021-0145879

(51) Int. Cl. H01S 5/06; H01S 5/068; H01S 5/062

(52) U.S. Cl. CPC H01S 5/0612; H01S 5/06812; H01S 5/062

(57) ABSTRACT

A wavelength stabilizer that performs wavelength stabilization using thermal characteristics of a laser diode without using additional components such as an etalon filter, and an optical module including the wavelength stabilizer, are proposed. The wavelength stabilizer for the optical module stabilizes the wavelength of laser light outputted from the laser diode and includes a controller constantly maintaining a junction temperature of the laser diode. The controller may constantly maintain the junction temperature of the laser diode through a thermoelectric cooler.

### CROSS-REFERENCE TO RELATED APPLICATION

The present application claims priority to Korean Patent Application No. 10-2021-0145879 filed on Oct. 28, 2021 in the Korean Intellectual Property Office, which is incorporated herein in its entirety by reference.

### BACKGROUND

### Technical Field

The present disclosure relates to an optical module, and more particularly, to a wavelength stabilizer for stabilizing the wavelength of laser light outputted from a laser diode (LD), and an optical module including the same.

### Description of Related Technology

An optical module is a device that performs transmission and reception functions using laser light. If the channel spacing is sufficiently secured in the optical module, there may be no problem in optical communication even if a shift of the output wavelength of some laser light occurs due to a change in ambient temperature or deterioration of the laser.

### SUMMARY

Accordingly, the present disclosure is intended to provide a wavelength stabilizer that performs wavelength stabilization using thermal characteristics of a laser diode without using additional components such as an etalon filter, and also provide an optical module including the same.

In addition, the present disclosure is intended to provide a wavelength stabilizer capable of solving a wavelength shift problem due to deterioration of a laser diode or a change in ambient temperature, and also provide an optical module including the same.

In addition, the present disclosure is intended to provide a wavelength stabilizer capable of simplifying the structure of an optical module, and also provide the optical module including the wavelength stabilizer.

According to the present disclosure, a wavelength stabilizer for an optical module that stabilizes a wavelength of laser light outputted from a laser diode may include a controller constantly maintaining a junction temperature of the laser diode.

The wavelength stabilizer may further include a thermoelectric cooler allowing the laser diode to be mounted thereon, and adjusting the temperature of the laser diode under control of the controller.

The controller may constantly maintain the junction temperature of the laser diode through the thermoelectric cooler.

The laser diode may include a substrate being in contact with the thermoelectric cooler and exchanging heat with the thermoelectric cooler, and a laser chip mounted on the substrate and outputting laser light.

The wavelength stabilizer may further include a current measurer measuring a current applied to the laser chip, a voltage measurer measuring a voltage applied to the laser chip, and a temperature measurer measuring a temperature of the substrate.

The controller may constantly maintain the junction temperature of the laser diode by adjusting the temperature of the substrate through the thermoelectric cooler.

Based on (3) of Equation 1 below, the controller may calculate the temperature (Tₛ₂) of the substrate such that a temperature change amount (Tₛ₁−Tₛ₂) of the substrate written on a left side is equal to a value written on a right side.

[Equation 1]

Tⱼ₁=Tₛ₁+Rₜₕ(I₁V₁−P₁) (1)

Tⱼ₂=Tₛ₂+Rₜₕ(I₂V₂−P₂) (2)

Under the condition Tⱼ₁=Tⱼ₂,

Tₛ₁−Tₛ₂=Rₜₕ(I₂V₂−I₁V₁)+Rₜₕ(P₁−P₂) (3)

(Tⱼ₁: Junction temperature at t1

Tⱼ₂: Junction temperature at t2

Tₛ₁: Substrate temperature at t1

Tₛ₂: Substrate temperature at t2

Rₜₕ: Thermal resistance [° C./W]

P₁: Light output at t1

P₂: Light output at t1)

The wavelength stabilizer may further include a light output measurer measuring a relative value (P₂/P₁) of a light output (P₁) at t1 and a light output (P₂) at t2.

The controller may calculate the temperature (Tₛ₂) of the substrate by using Equation 2 below.

[Equation 2]

Tₛ₁−Tₛ₂=Rₜₕ(I₂V₂−V₁)+P₁Rₜₕ(1 −P₂/P₁) (4)

When P₁=P₂ and V₁≈V₂ in an automatic power control (APC) mode, and when the current measurer measures a current relative value (I₂/I₁), the controller may calculate the temperature (Tₛ₂) of the substrate by using (7) of Equation 3 below.

[Equation 3]

Tₛ₁−Tₛ₂=Rₜₕ(I₂V₂−I₁V₁)+Rₜₕ(P₁−P₂) (3)

Tₛ₁−Tₛ₂=Rₜₕ(I₂V₂−I₁V₁) (when P₁=P₂) (5)

Tₛ₁−Tₛ₂=I₁V₁Rₜₕ(I₂V₂/I₁V₁−1) (6)

Tₛ₁−Tₛ₂=I₁V₁Rₜₕ(I₂/I₁−1) (V₁≈V₂) (7)

In addition, according to the present disclosure, an optical module may include a wavelength stabilizer stabilizing a wavelength of laser light outputted from a laser diode. The wavelength stabilizer may include a controller constantly maintaining a junction temperature of the laser diode.

According to the present disclosure, the wavelength stabilizer for the optical module performs wavelength stabilization using thermal characteristics of the laser diode without using additional components such as an etalon filter. That is, the wavelength stabilizer can constantly maintain the junction temperature of the laser diode, thereby stabilizing the wavelength of the outputted laser even if the laser diode deteriorates or the ambient temperature changes. As such, the junction temperature of the laser diode is constantly maintained by adjusting the temperature of the laser diode through the thermoelectric cooler on which the laser diode is mounted.

According to the present disclosure, because the wavelength stabilizer for the optical module can perform the wavelength stabilization by maintaining the junction temperature of the laser diode through the thermoelectric cooler, there is an advantage that the structure of the optical module is simplified and the manufacturing cost is lowered, compared to applying the etalon filter.

In addition, according to the present disclosure, the wavelength stabilizer can be used in the optical module for WDM or DWDM.

### BRIEF DESCRIPTION OF THE DRAWINGS

FIG. 1 is a diagram illustrating an optical module including a wavelength stabilizer according to an embodiment of the present disclosure.

FIG. 2 is a LIV graph for explaining a wavelength stabilization method using the wavelength stabilizer of FIG. 1 when there is no deterioration in a laser diode.

FIG. 3 is a LIV graph for explaining a wavelength stabilization method using the wavelength stabilizer of FIG. 1 when there is deterioration in a laser diode.

### DETAILED DESCRIPTION

However, the shift of the output wavelength of laser light in a channel spacing of 100 GHz or less as in an optical module for wavelength division multiplexing (WDM) causes a serious problem, so a wavelength stabilization technology is required. The wavelength stabilization is to prevent the shift of the output wavelength of laser light used for optical communication and thus maintain a constant output wavelength.

As a wavelength stabilization method, a method using the Fabry-Perot filter is used. This method is to monitor the current wavelength of laser light with the Fabry-Perot filter by using a part of the output of the laser and adjust the temperature of the laser through feedback from the circuit to the laser, thereby maintaining the laser wavelength desired by the user. As the Fabry-Perot filter, the etalon filter is used. The optical module to which the etalon filter is applied is also available for dense WDM (DWDM) with more than tens of channels.

The optical module to which the etalon filter is applied monitors the output light of the laser that has passed through the etalon filter, and adjusts the temperature of the laser with a thermoelectric cooler so that the laser can output the light of a desired wavelength through a wavelength stabilization algorithm based on the monitored output light.

As such, typically, the etalon filter and the module for performing a wavelength stabilization algorithm are essential for wavelength stabilization.

In addition, fine-tuning the angle of the etalon filter through the laser output light monitoring and the wavelength stabilization algorithm is a very difficult technique.

Also, in case of applying the etalon filter to the wavelength stabilization, the structure of the optical module becomes complicated and the manufacturing cost is also increased.

Now, embodiments of the present disclosure will be described in detail with reference to the accompanying drawings.

However, in the following description and the accompanying drawings, well known techniques may not be described or illustrated in detail to avoid obscuring the subject matter of the present disclosure. Through the drawings, the same or similar reference numerals denote corresponding features consistently.

The terms and words used in the following description, drawings and claims are not limited to the bibliographical meanings thereof and are merely used by the inventor to enable a clear and consistent understanding of the disclosure. Thus, it will be apparent to those skilled in the art that the following description about various embodiments of the present disclosure is provided for illustration purpose only and not for the purpose of limiting the disclosure as defined by the appended claims and their equivalents.

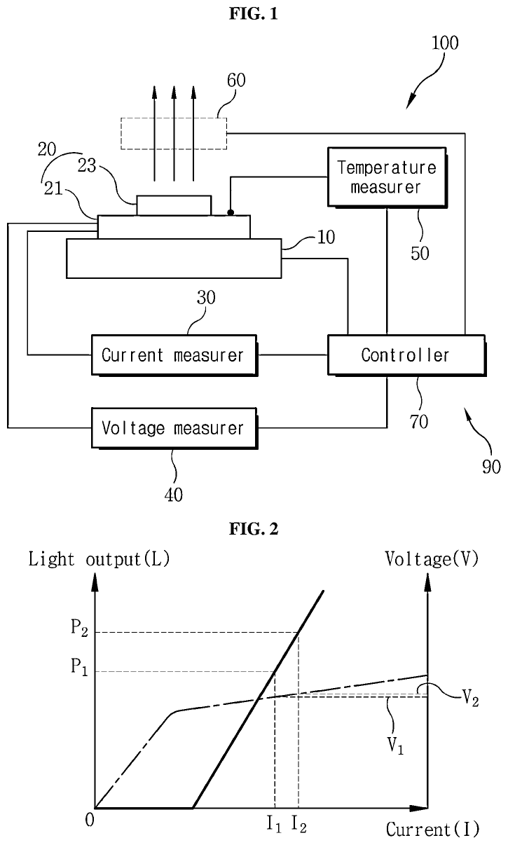

FIG. 1 is a diagram illustrating an optical module including a wavelength stabilizer according to an embodiment of the present disclosure.

Referring to FIG. 1, the optical module 100 according to an embodiment includes a wavelength stabilizer 90 that stabilizes the wavelength of laser light outputted from a laser diode 20. The wavelength stabilizer 90 includes a controller 70 that constantly maintains the junction temperature of the laser diode 20.

The wavelength stabilizer 90 according to an embodiment may further include a thermoelectric cooler 10, a current measurer 30, a voltage measurer 40, a temperature measurer 50, and a light output measurer 60.

In particular, the wavelength stabilizer 90 according to an embodiment performs wavelength stabilization by using the thermal characteristics of the laser diode 20 without the use of additional components such as a typical etalon filter. That is, the wavelength stabilizer 90 can constantly maintain the junction temperature of the laser diode 20, thereby stabilizing the wavelength of the outputted laser light even if the laser diode 20 deteriorates or the ambient temperature changes.

The optical module 100 according to an embodiment is a device that performs transmission and reception functions using laser light, and is referred to as an optical transceiver, an optical transponder, and the like. For example, the optical module 100 including the wavelength stabilizer 90 according to an embodiment may be used for WDM or DWDM.

In the optical module 100 according to an embodiment, the wavelength stabilizer 90 stabilizes the wavelength of the laser light outputted from the laser diode 20.

Now, the wavelength stabilizer 90 according to an embodiment will be described in detail.

The laser diode 20 includes a substrate 21 and a laser chip 23 mounted on the substrate 21 and outputting laser light. The substrate 21 receives a control signal and power required for the operation of the laser chip 23 and operates the laser chip 23.

Heat generated by the laser chip 23 is dissipated to the outside through the substrate 23 and the thermoelectric cooler 10.

The thermoelectric cooler 10 allows the laser diode 20 to be mounted thereon, and adjusts the temperature of the laser diode 20 under the control of the controller 70. For example, the thermoelectric cooler 10 dissipates heat generated during the operation of the laser diode 20 to the outside so that the laser diode 20 can maintain a constant temperature. Conversely, when the ambient temperature is lower than a suitable temperature for operating the laser diode 20, the thermoelectric cooler 10 can apply heat to the laser diode 20. In particular, for wavelength stabilization, the controller 70 constantly maintains the junction temperature of the laser diode 20 through the thermoelectric cooler 10.

In order for the thermoelectric cooler 10 to effectively adjust the temperature of the laser diode 20, the substrate 21 of the laser diode 20 is mounted on the thermoelectric cooler 10. That is, the substrate 21 has an upper surface for mounting the laser chip 23 and a lower surface being in contact with the thermoelectric cooler 10. The substrate 21 exchanges heat with the thermoelectric cooler 10 through surface contact, so that the temperature of the laser diode 20 is adjusted.

The controller 70 controls the temperature of the thermoelectric cooler 10 by adjusting the current applied to the thermoelectric cooler 10.

The reason why the wavelength stabilizer 90 constantly maintains the junction temperature of the laser diode 20 in an embodiment is to stabilize the wavelength of the laser light outputted from the laser diode 20. That is, the reason is that the wavelength of the laser light outputted from the laser diode 20 is influenced by the junction temperature of the laser diode 20, namely, the junction temperature of the laser chip 23.

In other words, if the junction temperature of the laser diode 20 is kept constant, the wavelength of the laser light can be stabilized.

In order to constantly maintain the junction temperature of the laser diode 20, the thermoelectric cooler 10 adjusts the temperature of the substrate 21 in an embodiment.

The temperature of the substrate 21 to constantly maintain the junction temperature of the laser diode 20 can be calculated as follows.

The current measurer 30 measures a current applied to the laser chip 23.

The voltage measurer 40 measures a voltage applied to the laser chip 23.

The temperature measurer 50 measures the temperature of the substrate 21. A point at which the temperature of the substrate 21 is measured may be a soldering point. As the temperature measurer 50, a thermocouple may be used.

Then, based on the current measured by the current measurer 30, the voltage measured by the voltage measurer 40, and the temperature of the substrate 21 measured by the temperature measurer 50, the controller 70 adjusts the temperature of the substrate 21 through the thermoelectric cooler 10 and thereby constantly maintains the junction temperature of the laser diode 20.

As shown in (3) of Equation 1 below, the controller 70 may calculate the temperature (Tₛ₂) of the substrate 21 such that the temperature change amount (Tₛ₁−Tₛ₂) of the substrate written on the left side is equal to a value written on the right side. The temperature (Tₛ₂) of the substrate 21 denotes the substrate temperature at t2, which is a certain time point after a time point t1. The time point t1 may be an initial time point.

[Equation 1]

Tⱼ₁=Tₛ₁+Rₜₕ(I₁V₁−P₁) (1)

Tⱼ₂=Tₛ₂+Rₜₕ(I₂V₂−P₂) (2)

Under the condition Tⱼ₁=Tⱼ₂,

Tₛ₁−Tₛ₂=Rₜₕ(I₂V₂−I₁V₁)+Rₜₕ(P₁−P₂) (3)

(Tⱼ₁: Junction temperature at t1

Tⱼ₂: Junction temperature at t2

Tₛ₁: Substrate temperature at t1

Tₛ₂: Substrate temperature at t2

Rₜₕ: Thermal resistance [° C./W]

P₁: Light output at t1

P₂: Light output at t1)

In Equation 1, the thermal resistance (Rₜₕ) denotes a thermal resistance between points at which the temperature of the substrate 21 is measured at the junction of the laser chip 23, and is provided as a set value. In this case, the point at which the temperature of the substrate 21 is measured denotes a point at which the temperature measurer 50 measures the temperature of the substrate 21.

Hereinafter, a process of calculating the temperature (Tₛ₂) of the substrate 21 by Equation 1 will be described with reference to FIG. 2. FIG. 2 is a LIV graph for explaining a wavelength stabilization method using the wavelength stabilizer 90 of FIG. 1 when there is no deterioration in a laser diode 20.

In FIG. 2, the solid line is an L-I curve showing a change in the light output of the laser diode 20 according to the applied power. The dashed-dotted line is an I-V curve showing a change in the voltage of the laser diode 20 according to the applied power.

First, from (1) and (2) in Equation 1, the junction temperature (Tⱼ₁) at t1 and the junction temperature (Tⱼ₂) at t2 can be calculated. Here, Tⱼ₁ is given as a value set as the initial junction temperature.

If Equation 1 is expanded under the condition of Tⱼ₁=Tⱼ₂ using (1) and (2) of Equation 1, (3) of Equation 1 can be obtained.

In (3) of Equation 1, the temperature (Tₛ₂) of the substrate 21 at t2 can be calculated. That is, because the remaining variables except Tₛ₂ are measured, calculated, or given as set values, Tₛ₂ can be calculated.

The controller 70 stabilizes the wavelength of the laser light by controlling the operation of the thermoelectric cooler 10 so that the substrate 21 has Tₛ₂ at the calculated t2.

The light output measurer 60 measures the light output of the laser diode 20. If the light output measurer 60 can measure both the light output (P₁) at t1 and the light output (P₂) at t2, the controller 70 can calculate the temperature (Tₛ₂) of the substrate 21 by (3) of Equation 1.

On the other hand, the light output (P₁) at t1, which is the initial value of the light output, can be given as a set value, and the light output measurer 60 cannot measure the absolute value of the light output (P₂) at t2, but it is possible to measure the relative value (P₂/P₁) of the light output (P₁) at t1 and the light output (P₂) at t2.

In this case, the controller 70 may calculate the temperature (Tₛ₂) of the substrate 21 by using (4) of Equation 2 obtained by modifying (3) of Equation 1.

[Equation 2]

Tₛ₁−Tₛ₂=Rₜₕ(I₂V₂−I₁V₁)+P₁Rₜₕ(1−P₂/P₁) (4)

Meanwhile, the reason why the wavelength stabilization is required in the optical module 100 is that the deterioration of the laser diode 20 occurs due to the use of the optical module 100. The deterioration of the laser diode 20 causes a shift in the wavelength of the laser light.

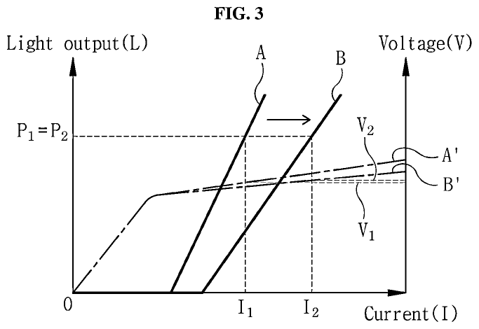

FIG. 3 is a LIV graph for explaining a wavelength stabilization method using the wavelength stabilizer 90 of FIG. 1 when there is deterioration in a laser diode 20.

Referring to FIG. 3, when the laser diode 20 is deteriorated, the light output is reduced for the same current.

Therefore, in optical communication, an automatic power control (APC) mode for a constant light output is generally used. Even if the laser diode 20 is deteriorated and the light output is reduced, the APC mode allows the light output to be constantly maintained by increasing the intensity of a driving current inputted to the laser diode 20.

In FIG. 3, A denotes an L-I curve showing a change in the light output of the laser diode 20 before deterioration, and B denotes an L-I curve showing a change in the light output of the deteriorated laser diode 20. That is, the change in the light output of the laser diode 20 shows the curve B shifted to right due to deterioration from the curve A before deterioration.

In addition, A′ is an I-V curve showing a change in the voltage of the laser diode 20 before deterioration, and B′ is an I-V curve showing a change in the voltage of the deteriorated laser diode 20. The curve A′ represents a voltage (V₁) for a current (I₁) at t1, and the curve B′ represents a voltage (V₂) for a current (I₂) at t2.

According to an embodiment, in the APC mode, the temperature (Tₛ₂) of the substrate 21 can be calculated by Equation 3 modified from (3) of Equation 1.

[Equation 3]

Tₛ₁−Tₛ₂=Rₜₕ(I₂V₂−I₁V₁)+Rₜₕ(P₁−P₂) (3)

Tₛ₁−Tₛ₂=Rₜₕ(I₂V₂−I₁V₁) (when P₁=P₂) (5)

Tₛ₁−Tₛ₂=I₁V₁Rₜₕ(I₂V₂/I₁V₁−1) (6)

Tₛ₁−Tₛ₂=I₁V₁Rₜₕ(I₂/I₁−1) (V₁≈V₂) (7)

That is, in (3) of Equation 3, because P₁=P₂ in the APC mode, the temperature (Tₛ₂) of the substrate 21 can be calculated by modified (5) of Equation 3.

The voltage measurer 40 measures a voltage applied to the laser chip 23.

At this time, the voltage (V₁) at t1 and the voltage (V₂) at t2 have almost the same value (V1≈V2).

The current measurer 30 measures the current applied to the laser chip 23. If the current measurer 30 can measure both the current (I₁) at t1 and the current (I₂) at t2, the controller 70 can calculate the temperature (Tₛ₂) of the substrate 21 by (5) or (6) of Equation 3.

On the other hand, the current (I₁) at t1, which is the initial value of the current, can be given as a set value, and the current measurer 30 cannot measure the absolute value of the current (I₂) at t2, but it is possible to measure the relative value (I₂/I₁) of the current (I₁) at t1 and the current (I₂) at t2. In this case, the controller 70 may calculate the temperature (Tₛ₂) of the substrate 21 by using (7) obtained by modifying (6) of Equation 3.

As described above, the wavelength stabilizer 90 according to embodiments of the present disclosure can constantly maintain the junction temperature of the laser diode 20, thereby stabilizing the wavelength of the outputted laser even if the laser diode 20 deteriorates or the ambient temperature changes. That is, the junction temperature of the laser diode 20 is constantly maintained by adjusting the temperature of the laser diode 20 through the thermoelectric cooler 10 on which the laser diode 20 is mounted.

Because the wavelength stabilizer 90 according to the present disclosure can perform the wavelength stabilization by maintaining the junction temperature of the laser diode 20 through the thermoelectric cooler 10, there is an advantage that the structure of the optical module 100 is simplified and the manufacturing cost is lowered, compared to applying the etalon filter.

While the present disclosure has been particularly shown and described with reference to an exemplary embodiment thereof, it will be understood by those skilled in the art that various changes in form and details may be made therein without departing from the scope of the present disclosure as defined by the appended claims.

What is claimed is:

1. A wavelength stabilizer for an optical module that stabilizes a wavelength of laser light outputted from a laser diode, the wavelength stabilizer comprising:
a controller configured to constantly maintain a junction temperature of the laser diode.

2. The wavelength stabilizer of claim 1, further comprising:
a thermoelectric cooler configured to allow the laser diode to be mounted thereon, and adjust the temperature of the laser diode under control of the controller,
wherein the controller is configured to constantly maintain the junction temperature of the laser diode through the thermoelectric cooler.

3. The wavelength stabilizer of claim 2, wherein the laser diode includes:
a substrate being in contact with the thermoelectric cooler and configured to exchange heat with the thermoelectric cooler; and
a laser chip mounted on the substrate and configured to output laser light.

4. The wavelength stabilizer of claim 3, further comprising:
a current measurer configured to measure a current applied to the laser chip;
a voltage measurer configured to measure a voltage applied to the laser chip; and
a temperature measurer configured to measure a temperature of the substrate, wherein the controller is configured to constantly maintain the junction temperature of the laser diode by adjusting the temperature of the substrate through the thermoelectric cooler.

5. The wavelength stabilizer of claim 4, wherein based on (3) of Equation 1 below, the controller is configured to calculate the temperature (Tₛ₂) of the substrate such that a temperature change amount (Tₛ₁−Tₛ₂) of the substrate written on a left side is equal to a value written on a right side,
[Equation 1]
Tⱼ₁=Tₛ₁+Rₜₕ(I₁V₁−P₁) (1)
Tⱼ₂=Tₛ₂+Rₜₕ(I₂V₂−P₂) (2)
Under the condition Tⱼ₁=Tⱼ₂,
Tₛ₁−Tₛ₂=Rₜₕ(I₂V₂−I₁V₁)+Rₜₕ(P₁−P₂) (3)
(Tⱼ₁: Junction temperature at t1
Tⱼ₂: Junction temperature at t2
Tₛ₁: Substrate temperature at t1
Tₛ₂: Substrate temperature at t2
Rₜₕ: Thermal resistance [° C./W]
P₁: Light output at t1
P₂: Light output at t1)

6. The wavelength stabilizer of claim 5, further comprising:
a light output measurer configured to measure a relative value (P₂/P₁) of a light output (P₁) at t1 and a light output (P₂) at t2,
wherein the controller is configured to calculate the temperature (Tₛ₂) of the substrate by using Equation 2 below,
[Equation 2]
Tₛ₁−Tₛ₂=Rₜₕ(I₂V₂−V₁)+P₁Rₜₕ(1 −P₂/P₁) (4)

7. The wavelength stabilizer of claim 5, wherein when P₁=P₂ and V₁≈V₂ in an automatic power control (APC) mode, and when the current measurer is configured to measure a current relative value (I₂/I₁), the controller is configured to calculate the temperature (Tₛ₂) of the substrate by using (7) of Equation 3 below,
[Equation 3]
Tₛ₁−Tₛ₂=Rₜₕ(I₂V₂−I₁V₁)+Rₜₕ(P₁−P₂) (3)
Tₛ₁−Tₛ₂=Rₜₕ(I₂V₂−I₁V₁) (when P₁=P₂) (5)
Tₛ₁−Tₛ₂=I₁V₁Rₜₕ(I₂V₂/I₁V₁−1) (6)
Tₛ₁−Tₛ₂=I₁V₁Rₜₕ(I₂/I₁−1) (V₁≈V₂) (7)

8. An optical module comprising:
a wavelength stabilizer configured to stabilize a wavelength of laser light outputted from a laser diode,
the wavelength stabilizer including a controller configured to constantly maintain a junction temperature of the laser diode.

9. The optical module of claim 8, wherein the wavelength stabilizer further includes:
a thermoelectric cooler configured to allow the laser diode to be mounted thereon, and adjust the temperature of the laser diode under control of the controller,
wherein the controller configured to constantly maintain the junction temperature of the laser diode through the thermoelectric cooler.

10. The optical module of claim 9, wherein the laser diode includes:
a substrate being in contact with the thermoelectric cooler and configured to exchange heat with the thermoelectric cooler; and
a laser chip mounted on the substrate and configured to output laser light.

11. The optical module of claim 10, wherein the wavelength stabilizer further includes:
a current measurer configured to measure a current applied to the laser chip;
a voltage measurer configured to measure a voltage applied to the laser chip; and
a temperature measurer configured to measure a temperature of the substrate,
wherein the controller is configured to constantly maintain the junction temperature of the laser diode by adjusting the temperature of the substrate through the thermoelectric cooler.

12. The optical module of claim 11, wherein based on (3) of Equation 1 below, the controller is configured to calculate the temperature (Tₛ₂) of the substrate such that a temperature change amount (Tₛ₁−Tₛ₂) of the substrate written on a left side is equal to a value written on a right side,
[Equation 1]
Tⱼ₁=Tₛ₁+Rₜₕ(I₁V₁−P₁) (1)
Tⱼ₂=Tₛ₂+Rₜₕ(I₂V₂−P₂) (2)
Under the condition Tⱼ₁=Tⱼ₂,
Tₛ₁−Tₛ₂=Rₜₕ(I₂V₂−I₁V₁)+Rₜₕ(P₁−P₂) (3)
(Tⱼ₁: Junction temperature at t1
Tⱼ₂: Junction temperature at t2
Tₛ₁: Substrate temperature at t1
Tₛ₂: Substrate temperature at t2
Rₜₕ: Thermal resistance [° C./W]
P₁: Light output at t1
P₂: Light output at t1)

13. The optical module of claim 12, wherein the wavelength stabilizer further includes:
a light output measurer configured to measure a relative value (P₂/P₁) of a light output (P₁) at t1 and a light output (P₂) at t2,
wherein the controller is configured to calculate the temperature (Tₛ₂) of the substrate by using Equation 2 below,
[Equation 2]
Tₛ₁−Tₛ₂=Rₜₕ(I₂V₂−V₁)+P₁Rₜₕ(1 −P₂/P₁) (4)

14. The optical module of claim 12, wherein when P₁=P₂ and V₁≈V₂ in an automatic power control (APC) mode, and when the current measurer measures a current relative value (I₂/I₁), the controller is configured to calculate the temperature (Tₛ₂) of the substrate by using (7) of Equation 3 below,
[Equation 3]
Tₛ₁−Tₛ₂=Rₜₕ(I₂V₂−I₁V₁)+Rₜₕ(P₁−P₂) (3)
Tₛ₁−Tₛ₂=Rₜₕ(I₂V₂−I₁V₁) (when P₁=P₂) (5)
Tₛ₁−Tₛ₂=I₁V₁Rₜₕ(I₂V₂/I₁V₁−1) (6)
Tₛ₁−Tₛ₂=I₁V₁Rₜₕ(I₂/I₁−1) (V₁≈V₂) (7).
